(19) United States
(12) Patent Application Publication
(10) Pub. No.: US 2007/0222487 A1
(43) Pub. Date: Sep. 27, 2007

(54) Circuit for generating initialization signal

(75) Inventor: Seung Eon Jin, Seoul (KR)

Correspondence Address: COOPER & DUNHAM, LLP, 1185 AVENUE OF THE AMERICAS, NEW YORK, NY, 10036, US

(73) Assignee: Hynix Semiconductor Inc.

(21) Appl. No.: 11/648,280

(22) Filed: Dec. 29, 2006

(30) Foreign Application Priority Data
Mar. 21, 2006 (KR) 10-2006-0025854

(51) Int. Cl. H03L 7/00

(52) U.S. Cl. 327/143

(57) ABSTRACT

An initialization signal generation circuit is provided which includes a voltage divider for dividing an external voltage, generating an enable signal, and outputting the enable signal to a first node, a controller including at least one fuse, and adjusting a voltage level of the enable signal according to a cutting of the at least one fuse, and a signal generator for generating an initialization signal of a semiconductor device in response to the enable signal of the first node.

### TECHNICAL FIELD

The present disclosure relates to a circuit for generating an initialization signal, and more particularly to an initialization signal generation circuit for generating an initialization signal of a semiconductor device, such that it corrects a change of an enable point of the initialization signal when the enable point of the initialization signal is changed to another point due to change of temperature or fabrication condition of the semiconductor device, thereby generating the corrected initialization signal having an appropriate voltage level at a suitable point.

### DESCRIPTION OF THE RELATED ART

Generally, a conventional circuit for generating an initialization signal of a semiconductor device (hereinafter referred to as an initialization signal generation circuit) is indicative of a specific circuit capable of initializing a semiconductor chip. In the meantime, in order to operate the semiconductor chip, the semiconductor device generally receives a power-supply voltage (VDD) from an external part. The voltage level of the received voltage (VDD) begins at 0V and gradually increases to a target voltage-level at a predetermined rate (i.e., a predetermined slope).

In this case, if all circuits of the semiconductor chip directly receive the aforementioned VDD voltage, they are affected by the increasing VDD voltage, resulting in the occurrence of malfunction or faulty operation. In order to prevent the malfunction or faulty operation from being generated, the semiconductor device includes an initialization signal generation circuit capable of enabling the initialization signal. Therefore, circuits of the semiconductor device can receive the VDD voltage having a stable voltage-level.

However, the above-mentioned conventional initialization signal generation circuit changes an enable point of an initialization signal to another point because operation conditions of NMOS or PMOS elements contained in the circuit can vary due to change of temperature or fabrication conditions, such that it may unavoidably generate an undesirable initialization signal lower or higher than a suitable voltage-level.

The above-mentioned problems of the conventional initialization signal generation circuit will hereinafter be described with reference to FIGS. 1˜3C.

FIG. 1 is a circuit diagram illustrating a conventional initialization signal generation circuit.

Referring to FIGS. 1˜3C, an external voltage VDD received in the semiconductor device gradually increases from an initial operation point of the semiconductor device to a predetermined voltage level at a predetermined rate. Two NMOS elements (N11, N12) and a PMOS (P11) are switched off during a specific section (a) in which the VDD voltage begins at 0V and is lower than the threshold voltages of the NMOS (N11) and the PMOS (P11). Therefore, an initialization signal (PWRUP: Power UP) generated from the inverter IV11 gradually increases along with the VDD voltage, as depicted in section (a) shown in FIG. 2.

Subsequently, if the VDD voltage becomes higher than the threshold voltages of the NMOS (N11) and the PMOS (P11), the NMOS (N11) and the PMOS (P11) are switched on.

A voltage divider 110 performs division of the VDD voltage, and applies the divided voltage to a gate of the NMOS (N12). In more detail, a node-A voltage (VR) divided by a resistor (R11) and turn-ON resistors of the NMOS (N11) is applied to the gate of the NMOS (N12). In this case, the VR voltage is denoted by [VDD×R12/(R11+R12)] (where R12 is indicative of turn-on resistance of the NMOS N11).

In this case, the NMOS (N12) is switched off in the section (b) shown in FIG. 2 in which the VR voltage is lower than the threshold voltage (Vt) of the NMOS (N12). The PMOS (P11) is firstly switched on because the VDD voltage is higher than a ground voltage (VSS) by a threshold voltage or more, such that the node B enters a high-level state in the section (b). The inverter IV11 receives the high-level signal, and buffers the received high-level signal, such that it generates an initialization signal (PWRUP) of a ground-voltage (VSS) level. Therefore, the initialization signal (PWRUP) has the ground-voltage (VSS) level in the section (b) prior to the switching-ON of the NMOS (N12).

If the VDD voltage continuously increases such that the VR voltage is higher than the threshold voltage (Vt) of the NMOS (N12), the NMOS (N12) reacts accordingly to the increased VDD voltage such that it is switched on. Therefore, the discharging of electric charges of the node B begins due to the switched-ON NMOS (N12). Subsequently, if the VDD voltage increases more, the VR voltage also increases more, such that a current signal discharged at the NMOS (N12) also increases.

If the discharge current of the NMOS (N12) increases to be capable of suitably coping with a charged current of the PMOS (P11), the node B is pull-down-driven to enter a ground level (VSS), and the inverter (IV11) receives/buffers the VSS signal, and generates the initialization signal (PWRUP) of the VDD level. Therefore, the initialization signal (PWRUP) is enabled to the VDD level at the section (c) shown in FIG. 2, such that this enable point acts as an initialization (i.e., Power UP) point of the semiconductor device.

However, the NMOS elements (N11 and N12) or the PMOS (P11) contained in the aforementioned initialization signal generation circuit have very weak resistance to the change of temperature or fabrication condition, such that their operation characteristics are changed very sensitively according to the temperature or fabrication condition. Therefore, threshold voltages or operation conditions of the above-mentioned NMOS or PMOS elements are easily changed to others, such that unexpected changes occur at a level-transition (also called a level-shift) point of the node A or B. As a result, an enable point of the initialization signal (PWRUP) is also changed to another point as depicted in FIG. 3B or 3C, such that the resultant initialization signal (PWRUP) is lower or higher than a suitable voltage level.

Typically, if a generation point of the initialization signal (PWRUP) of the semiconductor device (such as a DRAM) is lagging a suitable point, and the voltage level of the initialization signal (PWRUP) increases, generation of an internal power-supply signal is affected by the increased PWRUP signal, such that generation of an internal bias voltage is delayed, resulting in the occurrence of malfunction or faulty operation.

In the meantime, if the generation point of the PWRUP signal is leading the suitable point, and the voltage level of the PWRUP signal decreases, floating nodes (or others) of internal circuits are not initialized, resulting in the occurrence of malfunction or faulty operation.

In conclusion, the conventional initialization signal generation circuit may unavoidably change the enable point of the initialization signal to another point due to the change of temperature or fabrication condition, such that a malfunction or faulty operation unavoidably occurs in the semiconductor.

### SUMMARY

The present disclosure provides an initialization signal generation circuit for correcting a change of an enable point of the initialization signal when the enable point of the initialization signal is changed to another point due to change of temperature or fabrication condition, and enabling the initialization signal of an appropriate voltage level to be obtained at a suitable point, such that it can allow a semiconductor device to perform normal initialization operations.

In accordance with one aspect of the present disclosure, an initialization signal generation circuit is provided which includes: a voltage divider for dividing an external voltage, generating a first enable signal, and outputting the first enable signal to a first node, a controller including at least one fuse, and adjusting a voltage level of the first enable signal according to a cutting of the at least one fuse, and a signal generator for generating an initialization signal for a semiconductor device in response to the first enable signal of the first node.

Preferably, the controller includes a voltage divider which includes at least one resistor and at least one fuse, performs division of the external voltage, generates a second enable signal, and outputs the second enable signal to a second node, and a first pull-down element for pull-down-driving the first node upon receiving the second enable signal from the second node.

Preferably, the second enable signal adjusts its own voltage level according to a cutting or non-cutting of the at least one fuse.

Preferably, the voltage divider includes a first resistor and a first fuse which are located between a supply terminal of the external voltage and the second node, and a second resistor and a second fuse which are located between the second node and a ground terminal.

Preferably, the voltage divider includes a third resistor located between a supply terminal of the external voltage and the first node, and a second pull-down element for pull-down-driving the first node in response to a first voltage.

Preferably, the signal generator includes a third pull-down element for pull-down-driving a third node in response to the first enable signal, a pull-up element for pull-up-driving the third node in response to a second voltage, and a buffer for buffering a signal received from the third node.

Preferably, the at least one controller is connected in parallel to the second pull-down element.

Preferably, the first voltage is the external voltage, and the second voltage is a ground voltage.

In accordance with another aspect of the present disclosure, an initialization signal generation circuit is provided which comprises: a voltage divider for dividing an external voltage, generating a first enable signal, and outputting the first enable signal to a first node, a signal generator for generating an initialization signal for a semiconductor device in response to the first enable signal of the first node, and a controller operated by the first enable signal, including at least one fuse, and adjusting a voltage level of the initialization signal according to a cutting or non-cutting of the fuse. Preferably, the signal generator includes a first pull-down element for pull-down-driving a second node in response to the first enable signal, a first pull-up element for pull-up-driving the second node in response to a predetermined voltage signal, and a buffer for buffering a signal received from the second node.

Preferably, the controller adjust a voltage level of the second enable signal according to a cutting or non-cutting of the at least one fuse.

Preferably, the controller includes at least one control unit which includes a second pull-down element for pull-down-driving the second node in response to the first enable signal, a first fuse located between the second node and a ground terminal such that it is connected in series to the second pull-down element, a second pull-up element for pull-up-driving the second node in response to a voltage signal of the ground terminal, and a second fuse located between the second node and a supply terminal of the external voltage such that it is connected in series to the second pull-up element.

### BRIEF DESCRIPTION OF THE DRAWINGS

The above and other objects, features and other advantages of the subject matter of the present disclosure will be more clearly understood from the following detailed description taken in conjunction with the accompanying drawings, in which:

FIG. 1 shows a circuit diagram illustrating a conventional initialization signal generation circuit;

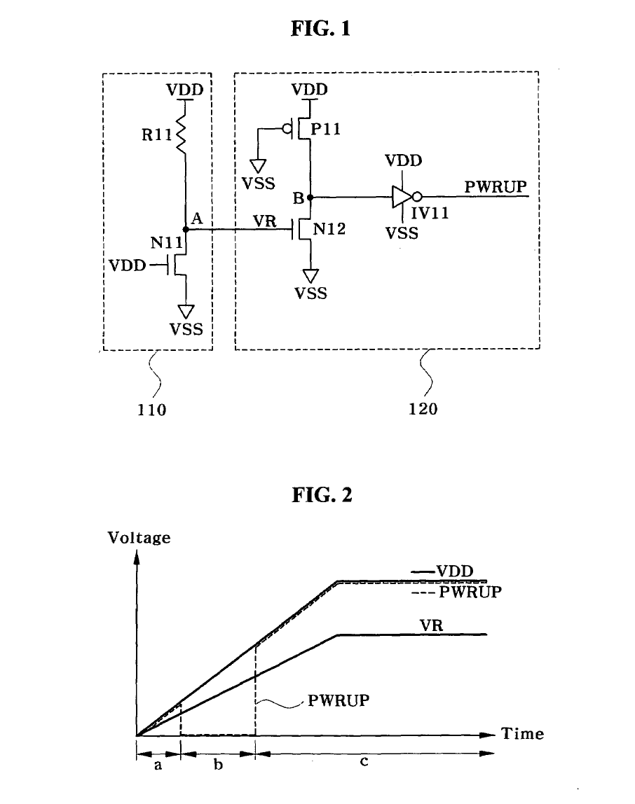

FIG. 2 shows a graph illustrating an initialization signal generated by the initialization signal generation circuit shown in FIG. 1;

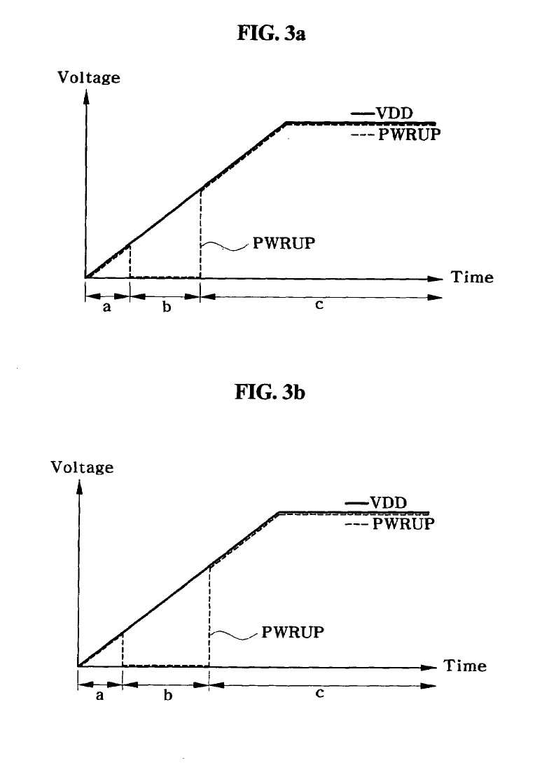

FIGS. 3A and 3C show graphs illustrating a comparison between a normal initialization signal and an abnormal initialization signal of the initialization signal generation circuit shown in FIG. 1;

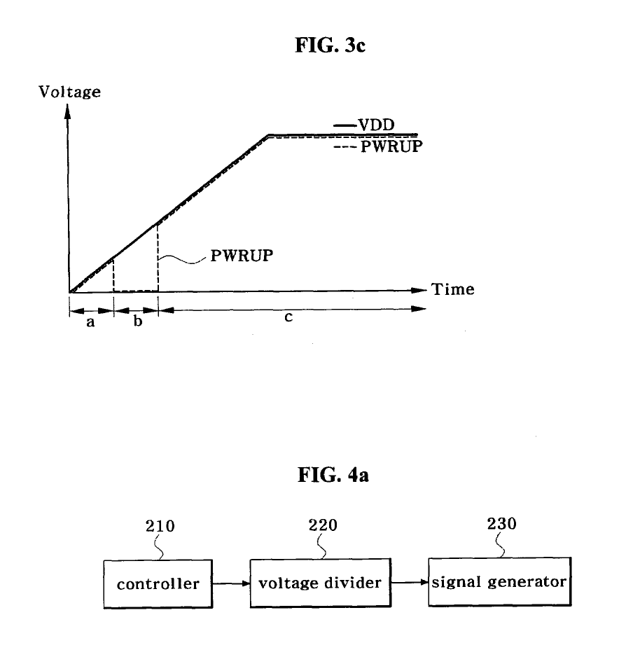

FIG. 4A shows a block diagram illustrating an example of an initialization signal generation circuit according to a first preferred embodiment of the present disclosure;

FIG. 4B shows a detailed circuit diagram illustrating an example of the initialization signal generation circuit of FIG. 4A;

FIG. 4C shows a circuit diagram illustrating another example of the initialization signal generation circuit of FIG. 4A;

FIGS. 5A and 5B show graphs illustrating a process for correcting an initialization signal of the initialization signal generation circuit according to the first preferred embodiment;

FIG. 6A shows a block diagram illustrating an initialization signal generation circuit according to a second preferred embodiment of the present disclosure;

FIG. 6B shows a detailed circuit diagram illustrating the initialization signal generation circuit of FIG. 6A; and

FIGS. 7A and 7B show graphs illustrating a process for correcting an initialization signal of the initialization signal generation circuit according to the second preferred embodiment.

### DESCRIPTION OF PREFERRED EMBODIMENTS

Now, preferred embodiments of the initialization signal generation circuit of the present disclosure will be described in detail with reference to the annexed drawings. In the drawings, the same or similar elements are denoted by the same reference numerals even though they are depicted in different drawings. In the following description, a detailed description of known functions and configurations incorporated herein will be omitted when it may make the subject matter of the present disclosure rather unclear.

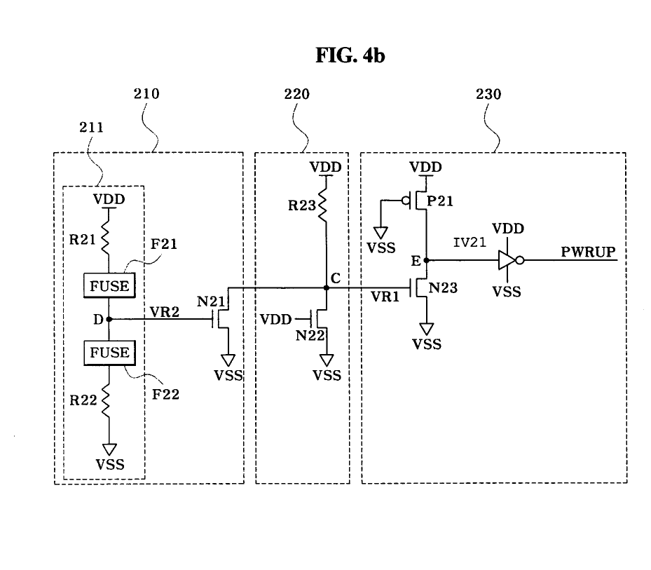

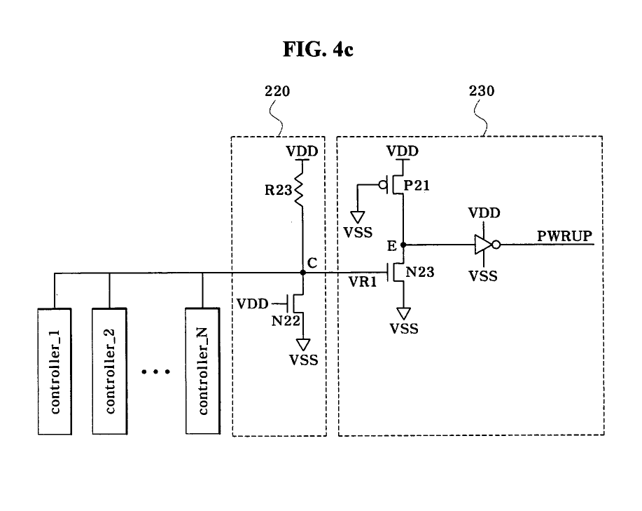

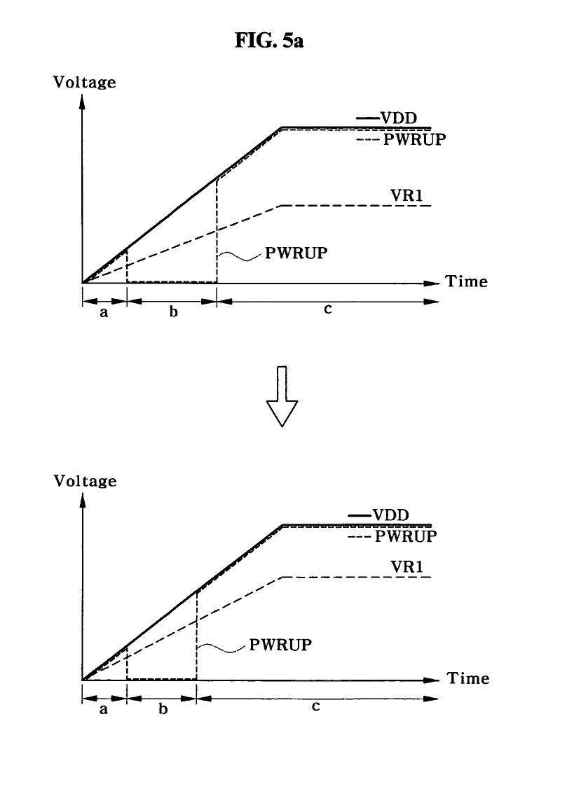

FIG. 4A shows a block diagram illustrating an initialization signal generation circuit according to a first preferred embodiment of the present disclosure. FIG. 4B is a detailed circuit diagram illustrating the initialization signal generation circuit of FIG. 4A.

The initialization signal generation circuit according to the first preferred embodiment will hereinafter be described with reference to FIGS. 4A and 4B.

Referring to FIGS. 4A and 4B, the initialization signal generation circuit includes a voltage divider 220, at least one controller 210, and a signal generator 230.

The voltage divider 220 performs division of an external voltage (VDD) to generate an enable signal (VR1), and outputs the enable signal (VR1) to a node (C). The controller 210 includes at least one fuse (F21, F22), and adjusts a voltage level of the enable signal (VR1) according to a cutting of the at least one fuse (F21 and F22). The signal generator 230 generates an initialization signal (PWRUP) of the semiconductor device in response to the enable signal (VR1) of the node (C).

The controller 210 includes a voltage divider 211 and an NMOS (N21).

The voltage divider 211 includes at least one resistor (R21, R22) and the at least one fuse (F21, F22), performs division of the VDD voltage to generate an enable signal (VR2), and outputs the enable signal (VR2) to the node D. The NMOS (N21) pull-down drives the node (C) upon receiving the enable signal (VR2) from the node (D).

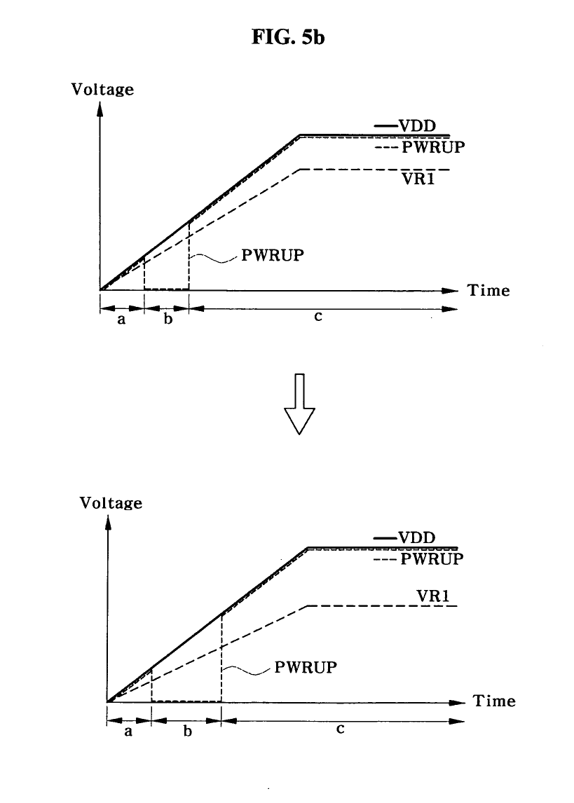

Operations of the above-mentioned initialization signal generation circuit according to an example of the first preferred embodiment will hereinafter be described with reference to FIGS. 4A and 5B. FIGS. 5A and 5B are graphs illustrating a process for correcting an initialization signal of the initialization signal generation circuit according to the first preferred embodiment.

Referring to 5A and 5B, an external voltage VDD received in the semiconductor device gradually increases in the range from an initial operation point of the semiconductor device to a predetermined voltage level at a predetermined rate. Three NMOS elements (N21, N22, N23) and a PMOS (P21) are switched off during a specific section (a) in which the VDD voltage begins at 0V and is lower than threshold voltages of the NMOS elements (N21, N22, N23) and the PMOS (P21). Therefore, an initialization signal (PWRUP: Power UP) generated from the inverter IV21 gradually increases along with the VDD voltage, as depicted in section (a) of FIGS. 5A and 5B.

Subsequently, if the VDD voltage becomes higher than the threshold voltages of the NMOS (N22) and the PMOS (P21), the NMOS (N22) and the PMOS (P21) are switched on. If the VDD voltage continuously increases and reaches a specific point, the NMOS (N21) for receiving the node-D voltage (VR2) at its gate is also switched on. The voltage divider 220 and the NMOS (N21) perform division of the VDD voltage, and transmit the divided VDD voltage to a gate of the NMOS (N23).

In other words, a node-C voltage (VR1) divided by a resistor (R23) and turn-ON resistors of the NMOSs (N22 and N21) is applied to the gate of the NMOS (N23). In this case, the VR1 voltage is denoted by [VDD×R100/(R23+R100)] (where R100 is indicative of composite resistance of the turn-ON resistances of the NMOSs (N21 and N22).

In this case, the NMOS (N23) is switched off in the section (b) in which the VR1 voltage is lower than the threshold voltage (Vt) of the NMOS (N23). The PMOS (P21) is firstly switched on because the VDD voltage is higher than a ground voltage (VSS) by a threshold voltage or more, such that the node E enters a high-level state in the section (b). The inverter IV21 receives the high-level signal, and buffers the received high-level signal, such that it generates an initialization signal (PWRUP) of a ground-voltage (VSS) level. Therefore, the initialization signal (PWRUP) has the ground-voltage (VSS) level in the section (b) prior to the switching-ON of the NMOS (N23).

If the VDD voltage continuously increases such that the VR1 voltage is higher than the threshold voltage (Vt) of the NMOS (N23), the NMOS (N23) replies to the increased VDD voltage, such that it is switched on. Therefore, the discharging of electric charges of the node E begins due to the switched-ON NMOS (N23). Subsequently, if the VDD voltage increases more, the VR1 voltage also increases more, such that a current signal discharged at the NMOS (N23) also increases.

If the discharge current of the NMOS (N23) increases to be capable of suitably coping with a charged current of the PMOS (P21), the node E is pull-down-driven to enter a ground level (VSS), and the inverter (IV21) receives/buffers the VSS signal, and generates the initialization signal (PWRUP) of the VDD level. Therefore, the initialization signal (PWRUP) is enabled to the VDD level at the section (c) as shown in FIGS. 5A˜5B, such that this enable point acts as an initialization (i.e., Power UP) point of the semiconductor device.

However, the NMOS elements (N22 and N23) or the PMOS (P21) contained in the aforementioned initialization signal generation circuit have very weak resistance to change of temperature or fabrication conditions, such that their operation characteristics are very sensitively changed according to the temperature or fabrication conditions. As a result, a generation point of the initialization signal (PWRUP) is lagging a suitable point as shown in an upper part of FIG. 5A, such that the PWRUP-voltage level may unavoidably increase.

In this case, the initialization signal generation circuit according to the first preferred embodiment determines the presence or absence of the cutting of the fuses F21 and F22 contained in the controller 210, such that it can correct the above-mentioned initialization signal (PWRUP) to have a suitable voltage level at a suitable point.

In other words, if the generation point of the PWRUP signal is lagging the suitable point and the PWRUP-voltage level increases, the initialization signal generation circuit performs the cutting of the fuse F21. Therefore, the NMOS (N21) is switched off, turn-ON resistance of the NMOS (N21) increases, composite resistance (R100) also increases, and the VR1 voltage denoted by [VDD×R100/(R23+R100)] also increases. As a result, turn-ON intensity of the NMOS (N23) increases, and a discharge current signal of the NMOS (N23) increases, such that the node E is rapidly pulled-down to the ground level (VSS).

In conclusion, the initialization signal (PWRUP) is enabled by the VDD level at a time point earlier than that of another case in which the fuse (F21) is not cut.

In this way, if the generation point of the initialization signal (PWRUP) is lagging the suitable point and a voltage level of the PWRUP signal increases, the above-mentioned initialization signal generation circuit according to the first preferred embodiment performs the cutting of the fuse (F21) contained in the controller 210, thereby advancing the enable point of the PWRUP signal. As a result, the PWRUP signal may be generated to have a suitable voltage-level at a suitable point as depicted in a lower part of FIG. 5A.

As can be seen from the upper part of FIG. 5B, although a generation point of the PWRUP signal is lagging a suitable point due to the change of temperature or fabrication conditions, and the PWRUP-voltage level decreases, the initialization signal generation circuit according to the first preferred embodiment of the present disclosure determines whether to cut the fuses (F21, F22) contained in the controller 210, such that it can correct the PWRUP signal to have a suitable voltage level at a suitable point.

In more detail, if the generation point of the PWRUP signal is leading the suitable point, the initialization signal generation circuit according to the preferred embodiment shown in FIG. 4b performs the cutting of the fuse (F22). The turn-ON resistance of the NMOS (N21) is reduced, and the composite resistance R100 is also reduced, such that the VR1 voltage denoted by [VDD×R100/(R23+R100)] is also reduced. Therefore, the turn-ON intensity of the NMOS (N23) is reduced, and a discharge current signal of the NMOS (N23) is reduced, such that the node E is pulled-down to the ground level (VSS). As a result, the PWRUP signal is enabled by the VDD level at a time later than another case in which the fuse (F22) is not cut.

In this way, if the generation point of the initialization signal (PWRUP) is leading the suitable point and a voltage level of the PWRUP signal decreases, the above-mentioned initialization signal generation circuit according to the preferred embodiment of FIG. 4b performs the cutting of the fuse (F22) contained in the controller 210, thereby delaying the enable point of the PWRUP signal. As a result, the PWRUP signal may be generated to have a suitable voltage-level at a suitable point as depicted in a lower part of FIG. 5B.

Accordingly, the initialization signal generation circuit according to the preferred embodiment shown in FIG. 4b adjusts the cutting of the fuses (F21, F22) contained in the controller 210, corrects the change of an enable point of the initialization signal even if the enable point of the initialization signal is changed to another point due to the change of temperature or fabrication conditions, and generates the resultant PWRUP signal capable of maintaining a suitable voltage level at a suitable point, thereby preventing a malfunction or faulty operation associated with the initialization (or power-up) operation from being generated.

FIG. 4C shows a circuit diagram illustrating an initialization signal generation circuit according to an example of the first preferred embodiment. As can be seen from FIG. 4C, a plurality of controllers 210 may be connected in parallel to the node (C) to more precisely adjust the VR1 voltage of the node (C), such that the enable point of the PWRUP signal can be more precisely controlled.

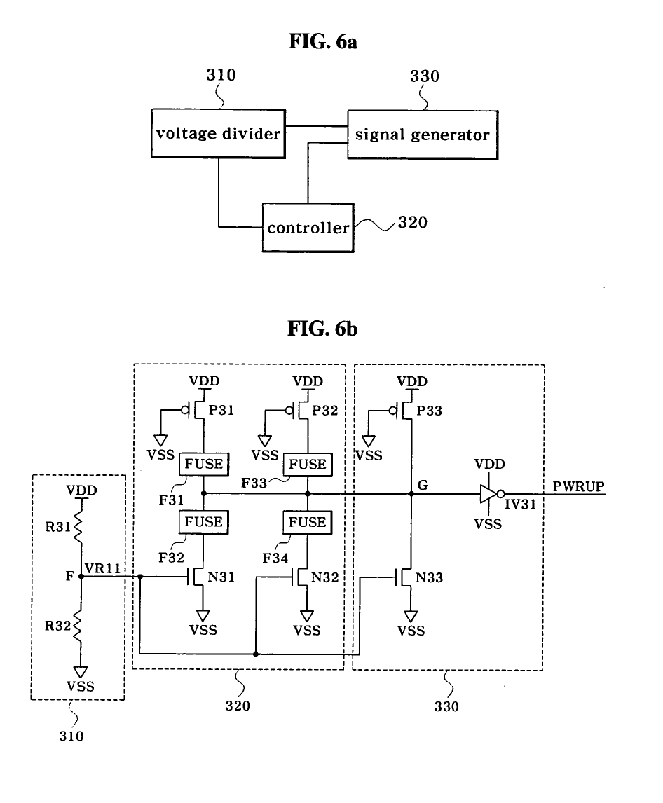

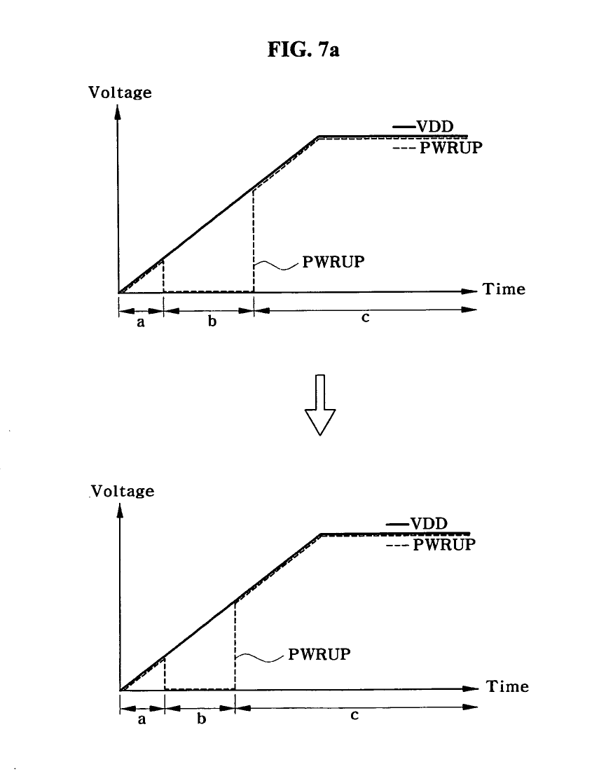

FIG. 6A shows a block diagram illustrating an initialization signal generation circuit according to a second preferred embodiment of the present disclosure. FIG. 6B shows a detailed circuit diagram illustrating the initialization signal generation circuit of FIG. 6A. The initialization signal generation circuit according to the second preferred embodiment will hereinafter be described with reference to FIGS. 6A and 6B.

Referring to FIGS. 6A and 6B, the initialization signal generation circuit according to the second preferred embodiment includes a voltage divider 310, a signal generator 330, and a controller 320.

The voltage divider 310 performs division of an external voltage (VDD) to generate an enable signal (VR11), and outputs the enable signal (VR11) to a node (F).

The signal generator 330 generates an initialization signal (PWRUP) for a semiconductor device in response to the enable signal (VR11) of the node (F).

The controller 320 is operated by the enable signal (VR11), includes at least one fuse (F31, F32, F33, F34), and adjusts a voltage level of the initialization signal (PWRUP) according to a cutting of the at least one fuse (F31, F32, F33, F34).

The controller 210 includes an NMOS (N31), a fuse (F32), a PMOS (P31), and a fuse (F31).

The NMOS (N31) pull-down-drives a node (G) in response to the enable signal (VR11). The fuse (F32) is located between a node (G) and a ground terminal (VSS) such that it is connected in series to the NMOS (N31). The PMOS (P31) pull-up-drives the node (G) in response to the ground voltage (VSS). The fuse (F31) is located between the node (G) and an external voltage (VDD), such that it is connected in series to the PMOS (P31).

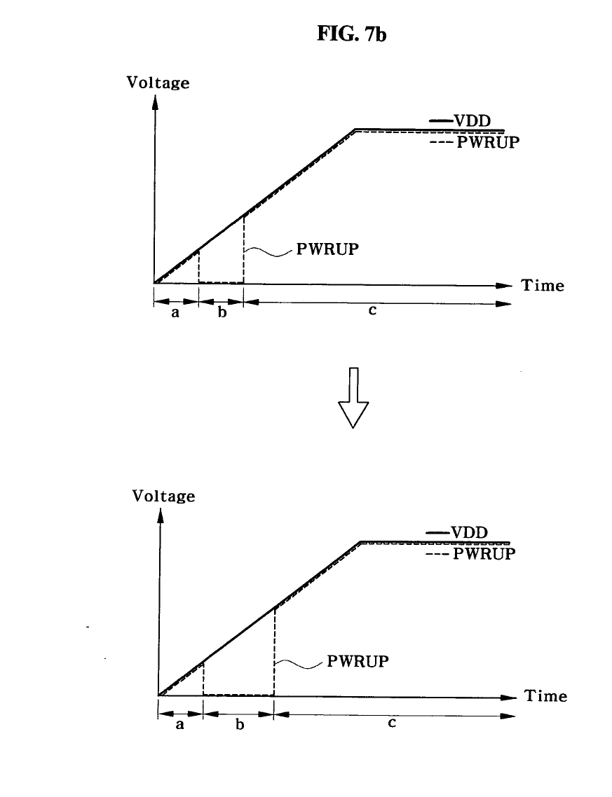

Operations of the above-mentioned initialization signal generation circuit according to the second preferred embodiment will hereinafter be described with reference to FIGS. 6A-7B.

FIGS. 7A and 7B are graphs illustrating a process for correcting an initialization signal of the initialization signal generation circuit according to the second preferred embodiment.

Referring to 7A and 7B, an external voltage VDD received in the semiconductor device gradually increases in the range from an initial operation point of the semiconductor device to a predetermined voltage level at a predetermined rate. Three NMOS elements (N31, N32, N33) and a PMOS (P31) are switched off during a specific section (a) in the same manner as in the above-mentioned first preferred embodiment of FIGS. 5A and 5B. Therefore, an initialization signal (PWRUP) generated from the inverter (IV31) gradually increases along with the VDD voltage, as depicted in (a) of FIGS. 7A and 7B.

Subsequently, if the VDD voltage becomes higher than the threshold voltages of the PMOS elements (P31, P32, P33), the PMOS elements (P31, P32, P33) are switched on, such that the node G enters a high-level state in the section (b). The inverter (IV31) receives the high-level signal, and buffers the received high-level signal, such that it generates an initialization signal (PWRUP) of a ground-voltage (VSS) level. Therefore, the initialization signal (PWRUP) has the ground-voltage (VSS) level in the section (b) prior to the switching-ON of the NMOS elements (N31, N32, N33).

If the VDD voltage continuously increases such that the VR11 voltage is higher than the threshold voltages (Vt) of the NMOS elements (N31, N32, N33), the NMOS elements (N31, N32, N33) responds to the increased VDD voltage, such that they are switched on. Therefore, the discharging of electric charges of the node G begins due to the above-mentioned NMOS elements (N31, N32, N33). Subsequently, if the VDD voltage increases more, the VR11 voltage also increases more, such that a current signal discharged at the NMOS elements (N31, N32, N33) also increases.

If the discharge current of the NMOS elements (N31, N32, N33) increases to be capable of suitably coping with a charged current of the PMOS (P33), the node G is pull-down-driven to enter a ground level (VSS), and the inverter (IV31) receives/buffers the VSS signal, and generates the initialization signal (PWRUP) of the VDD level. Therefore, the initialization signal (PWRUP) is enabled to the VDD level at the section (c) as shown in FIGS. 7A and 7B, such that this enable point acts as an initialization (i.e., Power UP) point of the semiconductor device.

However, the NMOS elements (N31, N32, N33) or the PMOS elements (P31, P32, P33) contained in the aforementioned initialization signal generation circuit have very weak resistance to change of temperature or fabrication conditions, such that their operation characteristics are very sensitively changed according to the temperature or fabrication conditions. As a result, a generation point of the initialization signal (PWRUP) is lagging a suitable point as shown in an upper part of FIG. 7A, such that the PWRUP-voltage level may unavoidably increase.

In this case, the initialization signal generation circuit according to the second preferred embodiment determines the presence or absence of the cutting of the fuses (F31, F33) contained in the controller 320, such that it can correct the above-mentioned initialization signal (PWRUP) to have a suitable voltage level at a suitable point.

In other words, if the generation point of the PWRUP signal is lagging the suitable point and the PWRUP-voltage level increases, the initialization signal generation circuit performs the cutting of the fuses (F31, F33). As a result, three NMOS elements (N31, N32, N33) for discharging the voltage of the node G remain whereas only a single PMOS (P33) remains, such that the voltage of the node G is pulled down to a low level at an earlier time point. Therefore, the PWRUP signal is enabled by the VDD level at a time point earlier than that of another case in which the fuses (F31, F33) are not cut.

In this way, if the generation point of the initialization signal (PWRUP) is lagging the suitable point and a voltage level of the PWRUP signal increases, the above-mentioned initialization signal generation circuit according to the second preferred embodiment performs the cutting of the fuses (F31, F33) contained in the controller 320, thereby advancing the enable point of the PWRUP signal. As a result, the PWRUP signal may be generated to have a suitable voltage-level at a suitable point as depicted in a lower part of FIG. 7A.

If there is a need to advance the enable point of the PWRUP signal, any one of the fuses (F31,F33) may be cut, thereby advancing the enable point of the PWRUP signal.

As can be seen from the upper part of FIG. 7B, although a generation point of the PWRUP signal is lagging a suitable point due to the change of temperature or fabrication conditions, and the PWRUP-voltage level decreases, the initialization signal generation circuit according to the second preferred embodiment determines whether to cut the fuses (F32, F34) contained in the controller 320, such that it can correct the PWRUP signal to have a suitable voltage level at a suitable point.

In more detail, if the generation point of the PWRUP signal is leading the suitable point, the initialization signal generation circuit according to the second preferred embodiment performs the cutting of the fuses (F32, F34). As a result, three PMOS elements (P31, P32, P33) for charging the voltage of the node G remain whereas only a single NMOS (N33) remains, such that the voltage of the node G is pulled down to a low level at a later time point. Therefore, the PWRUP signal is enabled by the VDD level at a time point later than that of another case in which the fuses (F32, F34) are not cut.

In this way, if the generation point of the initialization signal (PWRUP) is leading the suitable point and a voltage level of the PWRUP signal decreases, the above-mentioned initialization signal generation circuit according to the second preferred embodiment performs the cutting of the fuses (F32, F34) contained in the controller 320, thereby delaying the enable point of the PWRUP signal. As a result, the PWRUP signal may be generated to have a suitable voltage-level at a suitable point as depicted in a lower part of FIG. 7B.

If there is a need to more precisely delay the enable point of the PWRUP signal, any one of the fuses (F32, F34) may be cut, thereby delaying the enable point of the PWRUP signal.

Accordingly, the initialization signal generation circuit according to the second preferred embodiment adjusts the cutting of the fuses (F31, F32, F33, and F34) contained in the controller 320, corrects the change of an enable point of the initialization signal even if the enable point of the initialization signal is changed to another point due to the change of temperature or fabrication conditions, and generates the resultant PWRUP signal capable of maintaining a suitable voltage level at a suitable point, thereby preventing a malfunction or faulty operation associated with the initialization (or power-up) operation from being generated.

As apparent from the above description, an initialization signal generation circuit according to the present disclosure corrects a change of an enable point of the initialization signal when the enable point of the initialization signal is changed to another point due to the change of temperature or fabrication conditions, and enables the initialization signal of an appropriate voltage level at a suitable point, such that it can allow a semiconductor device to perform normal initial operations.

Although preferred embodiments of the present disclosure have been disclosed for illustrative purposes, those skilled in the art will appreciate that various modifications, additions and substitutions are possible, without departing from the scope and spirit of the disclosure and the accompanying claims. For example, elements and/or features of different examples and illustrative embodiments may be combined with each other and/or substituted for each other within the scope of this disclosure and appended claims.

The present application claims priority to Korean patent application No. 10-2006-0025854, filed on Mar. 21, 2006, which is incorporated herein in its entirety by reference.

What is claimed is:

1. An initialization signal generation circuit comprising:
a voltage divider for dividing an external voltage, generating a first enable signal, and outputting the first enable signal to a first node;
a controller including at least one fuse, and adjusting a voltage level of the first enable signal according to a cutting of the at least one fuse; and
a signal generator for generating an initialization signal for a semiconductor device in response to the first enable signal of the first node.

2. The initialization signal generation circuit according to claim 1, wherein the controller includes:
a voltage dividing circuit including at least one resistor and at least one fuse, dividing the external voltage, generating a second enable signal, and outputting the second enable signal to a second node; and
a first pull-down element for pull-down-driving the first node upon receiving the second enable signal from the second node.

3. The initialization signal generation circuit according to claim 2, wherein the second enable signal adjusts its own voltage level according to the cutting or non-cutting of the at least one fuse.

4. The initialization signal generation circuit according to claim 3, wherein the voltage divider includes:
a first resistor and a first fuse which are located between a supply terminal of the external voltage and the second node; and
a second resistor and a second fuse which are located between the second node and a ground terminal.

5. The initialization signal generation circuit according to claim 1, wherein:
the voltage divider includes:
a first resistor located between a supply terminal of the external voltage and the first node; and
a first pull-down element for pull-down-driving the first node in response to a first voltage, and
the signal generator includes:
a second pull-down element for pull-down-driving a third node in response to the first enable signal;
a pull-up element for pull-up-driving the third node in response to a second voltage; and
a buffer for buffering a signal received from the third node.

6. The initialization signal generation circuit according to claim 5, wherein the controller is connected in parallel to the first pull-down element.

7. The initialization signal generation circuit according to claim 5, wherein the first voltage is the external voltage, and the second voltage is a ground voltage.

8. An initialization signal generation circuit comprising:
a voltage divider for dividing an external voltage, generating a first enable signal, and outputting the first enable signal to a first node;
a signal generator for generating an initialization signal for a semiconductor device in response to the first enable signal of the first node; and
a controller operated by the first enable signal, including at least one fuse, and adjusting a voltage level of the initialization signal according to a cutting or non-cutting of the fuse.

9. The initialization signal generation circuit according to claim 8, wherein the signal generator includes:
a first pull-down element for pull-down-driving a second node in response to the first enable signal;
a first pull-up element for pull-up-driving the second node in response to a predetermined voltage signal; and
a buffer for buffering a signal received from the second node.

10. The initialization signal generation circuit according to claim 9, wherein the controller adjusts a voltage level of the second enable signal according to a cutting or non-cutting of the at least one fuse.

11. The initialization signal generation circuit according to claim 10, wherein the controller includes at least one control unit,
the control unit including:
a second pull-down element for pull-down-driving the second node in response to the first enable signal;
a first fuse located between the second node and a ground terminal such that it is connected in series to the second pull-down element;
a second pull-up element for pull-up-driving the second node in response to a voltage signal of the ground terminal; and
a second fuse located between the second node and a supply terminal of the external voltage such that it is connected in series to the second pull-up element.
